(19) United States
(12) Patent Application Publication
(10) Pub. No.: US 2026/0090373 A1
(43) Pub. Date: Mar. 26, 2026

(54) SEMICONDUCTOR STRUCTURE INCLUDING BONDING PART WITH HEAT-DISSIPATING UNIT AND METHOD FOR MANUFACTURING THE SAME

(71) Applicant: Taiwan Semiconductor Manufacturing Company, Ltd., Hsinchu (TW)

(72) Inventors: Chih-Chao CHOU, Hsinchu (TW); Che-Yi LIN, Hsinchu (TW); Ching-Wei TSAI, Hsinchu (TW); Chih-Hao WANG, Hsinchu (TW)

(73) Assignee: Taiwan Semiconductor Manufacturing Company, Ltd., Hsinchu (TW)

(21) Appl. No.: 18/898,158

(22) Filed: Sep. 26, 2024

(51) Int. Cl. H01L 23/367; H01L 23/00; H01L 23/373; H01L 23/522

(52) U.S. Cl. CPC H10W 40/22; H10W 40/255; H10W 40/257; H10W 20/40; H10W 72/01355; H10W 72/07331; H10W 72/321; H10W 72/322; H10W 72/353; H10W 72/355

(57) ABSTRACT

A method for manufacturing a semiconductor structure includes: forming a device portion and a front interconnect portion on a base substrate; forming a first bonding part on the front interconnect portion opposite to the device portion, the first bonding part including a first bonding layer and heat-dissipating elements formed in the first bonding layer, a thermal resistance of the heat-dissipating elements being smaller than a thermal resistance of the first bonding layer; forming a second bonding part on a carrier substrate; and performing a bonding process to bond the second bonding part to the first bonding part.

### BACKGROUND

In advanced node applications, power rails are formed at a back side of semiconductor devices. Heat generated during operation of such semiconductor devices is dissipated through a front side of the semiconductor devices. There is a need to develop novel structures and methods to further enhance the heat dissipation of the semiconductor devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor structure in accordance with some embodiments.

FIGS. 2 to 13 are schematic views illustrating intermediate stages of the method for manufacturing the semiconductor structure in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “bottommost,” “upper,” “uppermost.” “lower,” “lowermost,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The present disclosure is directed to a semiconductor structure including a bonding part with a heat-dissipating unit, and a method for manufacturing the same. The semiconductor structure includes a device portion, a front interconnect portion, a back interconnect portion, and a carrier substrate. The front interconnect portion and the back interconnect portion are disposed on and sandwiching the device portion. The carrier substrate is bonded to the front interconnect portion through a first bonding part and a second bonding part. The first bonding part is disposed on the front interconnect portion opposite to the device portion. The second bonding part is disposed between the carrier substrate and the first bonding part. The first bonding part includes a first bonding layer and a heat-dissipating unit disposed in and penetrating through the first bonding layer in a vertical direction. Specifically, the heat-dissipating unit includes heat-dissipating elements that are spaced apart from each other in a horizontal direction transverse (e.g., perpendicular to) to the vertical direction. A thermal resistance of the heat-dissipating unit is smaller than a thermal resistance of the first bonding layer. Each of the heat-dissipating elements serves as a thermal bridge to permit effective thermal conduction therethrough. Such heat-dissipating unit is configured to enhance dissipation of heat energy, if any, generated in hot zone area(s) of the device portion, through the front interconnect portion, the first bonding part, the second part and the carrier substrate, so as to minimize speed degradation of the device portion. In the method for manufacturing such semiconductor structure, the first bonding part is formed on the front interconnect portion which is initially formed on the device portion, while the second bonding part is formed on the carrier substrate that is initially formed independently from the device portion, and subsequently the first and second bonding parts are bonded to each other through a bonding process. In forming the first bonding part, the heat-dissipating elements (which include or are made of a heat-dissipating material) are formed to account for a predetermined surface percentage out of a bonding area between the first bonding part and the second bonding part, so as to minimize effects, if any, brought to the topography and bonding capability of the first bonding part. For instance, the heat-dissipating elements are formed with a predetermined density, critical dimension, and/or pitch. The heat-dissipating elements may have different arrangements, and may be formed at predetermined locations in the first bonding layer so as to fit in different product design of the semiconductor structure. In addition, the heat-dissipating elements can be easily formed in the first bonding layer using similar processes and/or conditions for forming conductive features in the front interconnect portion, without having to develop new processes.

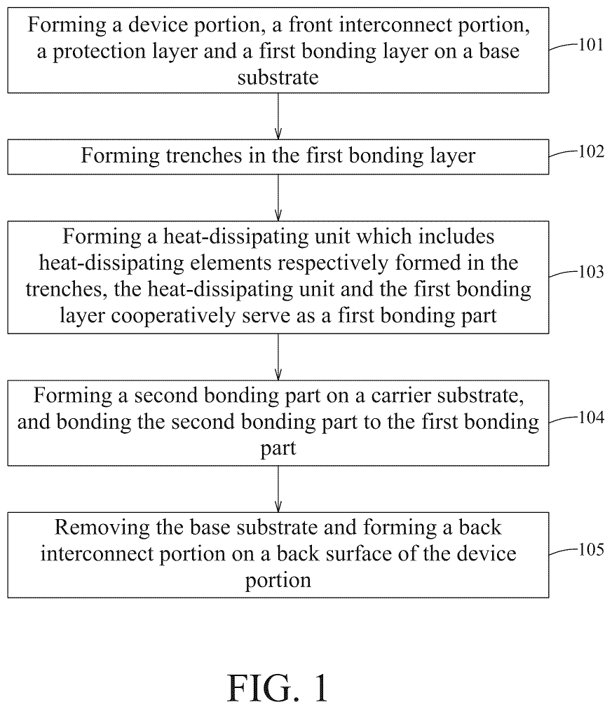

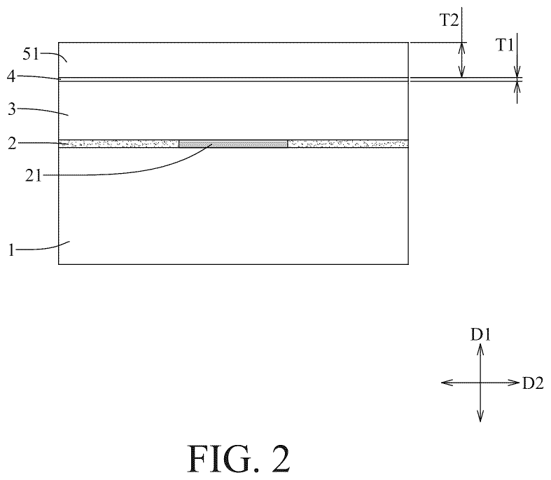

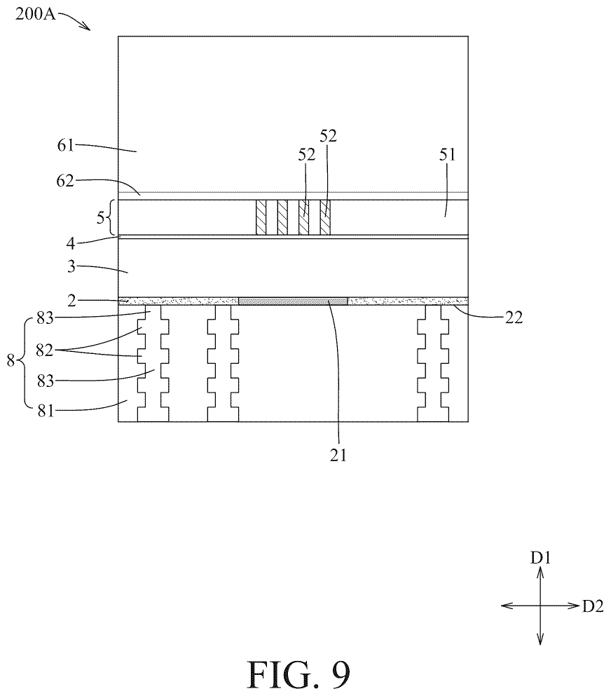

FIG. 1 is a flow diagram illustrating a method for manufacturing the semiconductor structure (for example, the semiconductor structures 200A to 200E respectively shown in FIGS. 9 to 13) in accordance with some embodiments. FIGS. 2 to 13 illustrate schematic views of intermediate stages of the method in accordance with some embodiments. Some repeating structures are omitted in FIGS. 2 to 13 for the sake of brevity. Additional steps can be provided before, after or during the method, and some of the steps described herein may be replaced by other steps or be eliminated.

Referring to FIG. 1 and the example illustrated in FIG. 2, the method begins at step 101, where a device portion 2, a front interconnect portion 3, a protection layer 4 and a first bonding layer 51 are sequentially formed on a base substrate 1 in a vertical direction D1.

The base substrate 1 may be made of elemental semiconductor materials, such as crystalline silicon, diamond, or germanium; compound semiconductor materials, such as silicon carbide, gallium arsenide, indium arsenide, or indium phosphide; or alloy semiconductor materials, such as silicon germanium, silicon germanium carbide, gallium arsenide phosphide, or gallium indium phosphide. The base substrate 1 may be doped with p-type impurities or n-type impurities, or undoped. In addition, the base substrate 1 may be a bulk silicon substrate, a silicon-on-insulator (SOI) substrate, or a germanium-on-insulator (GOI) substrate. In some embodiments, the base substrate 1 may be made of silicon. Other suitable materials for forming the base substrate 1 are within the contemplated scope of disclosure.

The device portion 2 may include one or more devices, such as logic devices (e.g. transistors), or the likes, but are not limited thereto. Examples of the transistors are fin type field-effect transistor (FET), gate-all-around (GAA) transistor, planar transistor, complementary FET, 2D transistor, or the likes. Other suitable devices may be included in the device portion 2. In some embodiments, the device portion 2 may include devices, semiconductor fins on which the devices are formed, and isolation features disposed to alternate the semiconductor fins. As the devices are in operation, heat is generated, and one or more area(s) of the device portion 2, especially where the devices are densely packed, may have a temperature relatively higher than other areas of the device portion 2. Each of such areas having relatively higher temperature may be known as a hot zone area 21. Thermal energy in the hot zone area(s) 21 are to be dissipated away, since the high temperature may undesirably result in speed degradation of the devices. In FIGS. 2 to 12, only one hot zone area 21 is shown, but is not limited thereto. Number of the hot zone areas 21 may vary case by case. In some embodiments, based on different product designs, location(s) of the hot zone area(s) 21 may be well identified. In other embodiments, number and location(s) of the hot zone area(s) 21 may not be known. Each of the devices may have one or more hot zone areas 21. The term “hot zone area” refers to an area in the device portion 2 that has a temperature higher than other areas of the device portion 2 during operation. Please note that only one of the hot zone areas 21 is shown in FIGS. 2 to 12 and described in following paragraphs.

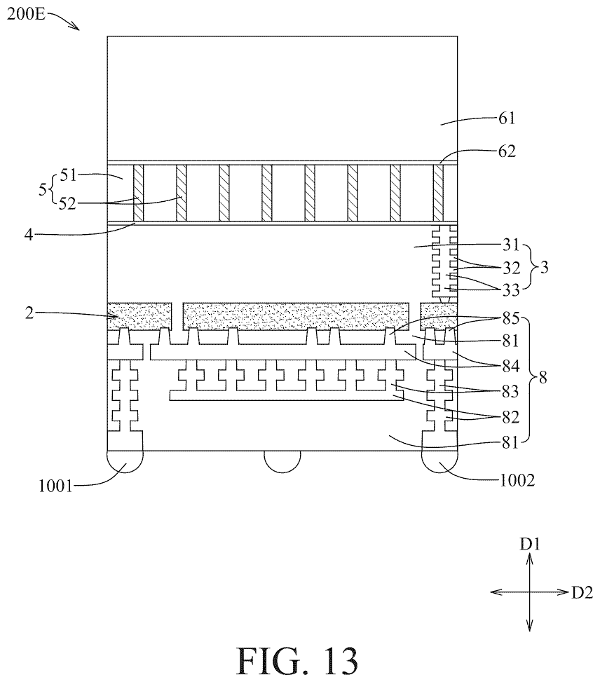

The front interconnect portion 3 is formed at a front side of the device portion 2. Further referring to FIG. 13, the front interconnect portion 3 includes an interlayer dielectric (ILD) feature 31, and one or more conductive features 32, 33 that are formed in the ILD feature 31. Please note that although the ILD feature 31 and the conductive features 32, 33 are not illustrated in the front interconnect portion 3 shown in FIGS. 2 to 12, the front interconnect portion 3 in FIGS. 2 to 12 may also include the ILD feature 31 and the conductive features 32, 33 similar to those shown in FIG. 13. The ILD feature 31 may include a dielectric material, such as a low dielectric constant (low K) material, but are not limited thereto. For instance, the dielectric material may be silicon oxide, silicon nitride, SiON, phosphosilicate glass (PSG), borophosphosilicate glass (BPSG), spin-on glass (SOG), fluorosilicate glass (FSG), carbon-doped silicon oxide (e.g., SiCOH), xerogel, aerogel, parylene, divinylsiloxane-bis-benzocyclobutene-based (BCB-based) dielectric material, polyimide, or the like, or combinations thereof. In some embodiments, the conductive features 32 may each serve as a metal layer or a metal line, while the conductive features 33 may each serve as a contact via. Each of the conductive features 32, 33 independently includes an electrically conductive material, such as a metallic material, e.g., copper (Cu), silver (Ag), gold (Au), aluminum (Al), nickel (Ni), cobalt (Co), ruthenium (Ru), iridium (Ir), platinum (Pt), palladium (Pd), osmium (Os), tungsten (W), molybdenum (Mo), tantalum (Ta), or alloys thereof, or the likes. Other suitable materials and/or elements for the front interconnect portion 3 are within the contemplated scope of the present disclosure.

The protection layer 4 is configured to protect the front interconnect portion 3, so as to prevent any of the metallic material present in the front interconnect portion 3 to be in contact with other elements above the front interconnect portion 3 (e.g., an oxide material of the first bonding layer 51). In addition, the conductive features 32, 33 in the front interconnect portion 3 are insulated from heat-dissipating elements 52 of a heat-dissipation unit (see FIG. 13) of the first bonding part 5, but are not limited thereto. In some embodiments, the protection layer 4 includes silicon nitride, or the likes, but is not limited thereto. Referring back to FIG. 2, the protection layer 4 may have a thickness T1 ranging from about 0.01 μm to about 0.05 μm, such as from about 0.01 μm to about 0.03 μm, or from about 0.03 μm to about 0.05 μm, but is not limited thereto. Such thickness range permits sufficient protection provided to the front interconnect portion 3 without exhibiting additional and undesired thermal resistance between the device portion 2 and the carrier substrate 61 (see FIG. 9). Other suitable materials and/or thickness for the protection layer 4 are within the contemplated scope of the present disclosure.

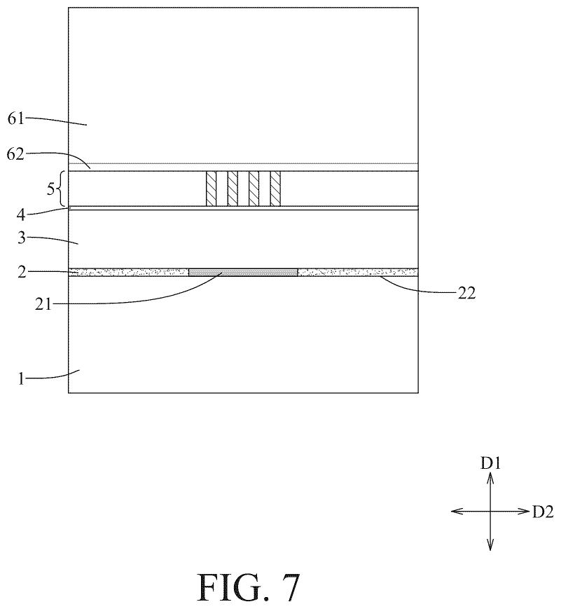

The first bonding layer 51 is formed on the front interconnect portion 3 opposite to the device portion 2, and serves as a main bonding surface so that the front device portion 2 and the front interconnect portion 3 are bonded to a carrier substrate 61 (see FIG. 7) through the first bonding layer 51. The first bonding layer 51 may include or may be made of silicon oxide, or the like, but is not limited thereto. The first bonding layer 51 may be formed over the protection layer 4 by a deposition process, such as chemical vapor deposition (CVD), or atomic layered deposition (ALD), but is not limited thereto. Other suitable materials and/or processes for forming the first bonding layer 51 are within the contemplated scope of the present disclosure. In some embodiments, the first bonding layer 51 has a thickness T2 ranging from about 0.1 μm to about 1.2 μm, such as from about 0.2 μm to about 1.2 μm. Please note that, although the first bonding layer 51, with such thickness range, may be considered as a relatively thick first bonding layer, heat dissipation of the semiconductor structure of the present disclosure is still improved in comparison with general practice, due to the configuration of the heat-dissipating unit. In addition, such relatively thick first bonding layer 51 permits the heat-dissipation unit in the subsequent steps to be formed more easily.

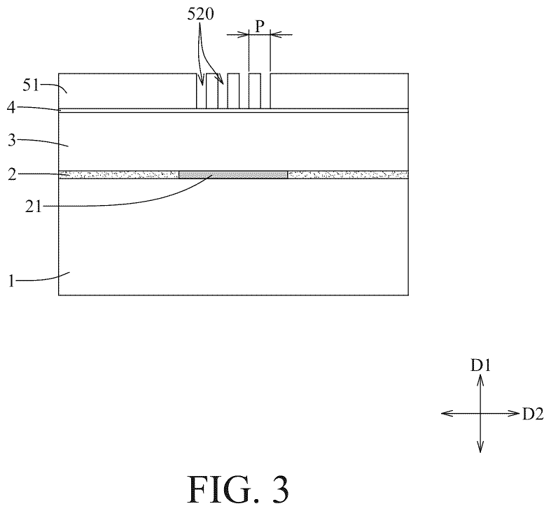

Referring to FIG. 1 and the example illustrated in FIG. 3, the method proceeds to step 102, where trenches 520 are formed at predetermined locations in the first bonding layer 51, respectively. Each of the trenches 520 are spaced apart from each other in a horizontal direction D2 transverse to the vertical direction D1. Each of the trenches 520 extends from an upper surface of the first bonding layer 51 to a lower surface of the first bonding layer 51 (so as to expose the element therebeneath, e.g., the protection layer 4).

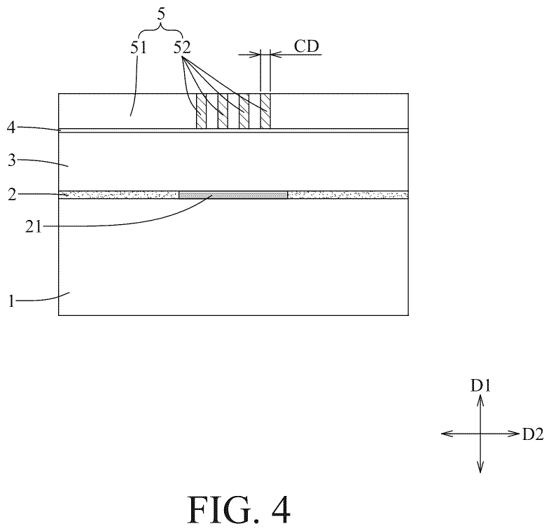

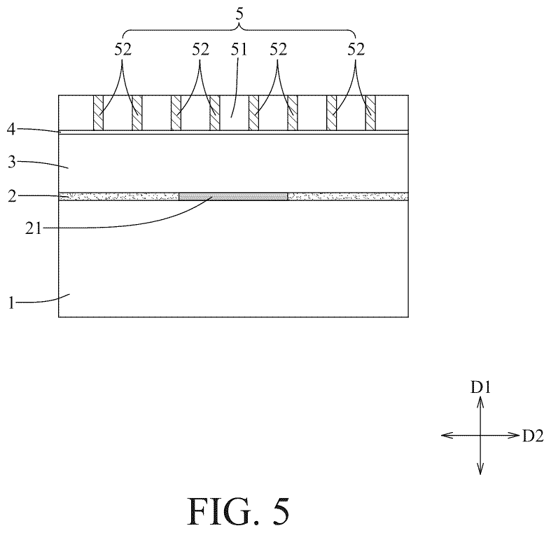

In some embodiments, the trenches 520 are formed by a patterning process, which includes: forming a mask layer (not shown) over the structure shown in FIG. 2; forming the mask layer into a patterned mask (not shown) through a photolithography process and an etching process; patterning the first bonding layer 51 through the patterned mask so as to form the trenches 520 in the first bonding layer 51 using an etching process, but is not limited thereto. The trenches 520 are to be filled with a heat-dissipating material in subsequent process, so as to form the heat-dissipating unit (which includes the heat-dissipating elements 52, see FIGS. 4 and 5) in the first bonding layer 51. In some embodiments, the mask layer may be a hard mask layer or a photoresist layer. Therefore, arrangement and/or positions of each of the trenches 520 may be determined based on a product design of the semiconductor structure and/or requirement of heat dissipating capability of the heat-dissipating unit.

Referring to FIG. 1 and the examples illustrated in FIGS. 4 and 5, the method proceeds to step 103, where the heat-dissipating unit is formed in the first bonding layer 51. The heat-dissipating unit and the first bonding layer 51 cooperatively serve as a first bonding part 5 which is formed on the front interconnect portion 3 opposite to the device portion 2, and which is to be bonded to a second bonding part 62 and a carrier substrate 61 (see FIG. 7) in a subsequent step.

The heat-dissipating unit is configured to facilitate heat energy dissipating away from the device portion 2 and the front interconnect portion 3 therethrough. The heat-dissipating unit penetrates through the first bonding layer 51 in the vertical direction D1. The heat-dissipating unit may include the heat-dissipating elements 52 that are respectively formed in the trenches 520 (see FIG. 3), and that are spaced apart from each other in the horizontal direction D2. Each of the heat-dissipating elements 52 extends from the upper surface of the first bonding layer 51 to the lower surface of the first bonding layer 51. The heat-dissipating unit, or the heat-dissipating elements 52, are insulated from the front interconnect portion 3 by the protection layer 4, so as to prevent the heat-dissipation elements 52 from being in direct contact with the conductive elements 32, 33 (see FIG. 13) present in the front interconnect portion 3.

In order to achieve effective heat dissipation, the heat-dissipating elements 52 of the heat-dissipating unit includes a heat-dissipating material, which is thermally conductive to achieve effective conduction of heat energy. The heat-dissipating material may have a thermal resistance smaller than (or a thermal conductivity higher than) that of the material of the first bonding layer 51. In some embodiments, the heat-dissipating material may be a metallic material, such as copper (Cu), tungsten (W), cobalt (Co), ruthenium (Ru), silver (Ag), other suitable materials, or combinations thereof, but are not limited thereto. In other embodiments, the heat-dissipating material may be diamond, boron nitride (BN), aluminum nitride (AlN), silicon carbide (SiC), or combinations thereof, but are not limited thereto.

It should be noted that it is important to seek balance between the heat-dissipating capability of the heat-dissipating unit, and the topography (e.g., smoothness of an upper surface) of the first bonding part 5 and bonding capability of the same (with the second bonding part 62, see FIG. 7). In some embodiments, the metallic material may occupy a surface of the first bonding part 5 in an amount not greater than approximately 30%, so as to retain good topography and bonding capability of the first bonding part 5, and to keep stress exerting onto the structure from the metallic heat-dissipating elements 52 at a relatively low level so as to avoid warpage of the wafer. In other words, as the first bonding part 5 and the second bonding part 62 are bonded to each other to have a bonding area therebetween, a projection of the heat-dissipating elements 52 (of the heat-dissipating unit) on the bonding area has a surface area that accounts for less than approximately 30% of the bonding area, such as from about 10% to about 30%. Such percentage of the surface area is known as the surface percentage of the heat-dissipating elements 52. In some other embodiments, the surface area accounts for less than approximately 10% of the bonding area, such as from about 2.5% to about 5%. Such percentage of the surface area may be controlled by adjusting distribution and/or location of the heat-dissipating elements 52 in the first bonding layer 51, as well as pitch and critical dimension of the heat-dissipating elements 52. For instance, in some embodiments, in forming the trenches 520 (see FIG. 3), the trenches 520 may have a pitch (denoted by “P”) ranging from about 0.1 μm to about 0.5 μm (which is equivalent to the pitch of the heat-dissipating elements 52). In other embodiments, each of the heat-dissipating elements 52 (see FIG. 4) may have a critical dimension (denoted by “CD”) ranging from about 0.05 μm to about 0.25 μm. Each of the heat-dissipating elements 52 is formed with a relatively small metal piece inserted into the first bonding layer 51, so as to minimize effect exerted on the topography of the first bonding part 5.

The distribution and location of the heat-dissipating elements 52 of the heat-dissipating unit may be determined based on product design of the semiconductor structure, and/or practical needs, such as requirement of heat-dissipating capability.

As shown in FIG. 4, in some embodiments, the heat-dissipating unit is formed in merely a region of the first bonding layer 51, and the heat-dissipating elements 52 are distributed within the region, while other regions of the first bonding layer 51 are steered clear of the heat-dissipating unit. The heat-dissipating elements 52 of such heat-dissipating unit are known as local bridges. In certain embodiments, when the hot zone area(s) 21 of the device portion 2 are well identified and only account for a relatively small area out of the total area of device portion 2, the heat-dissipating unit is formed at a region in the first bonding layer 51 which is directly above the hot zone area(s) 21. That is, the local bridges, i.e., the heat-dissipating elements 52, are distributed in the region of the first bonding layer 51 in position corresponding to the well-identified hot zone area(s) 21, but not in other regions of the first bonding layer 51. As such, heat generated in the hot zone area 21 is directly and effectively transmitted to the heat-dissipating unit. In some embodiments, a projection of the hot zone areas 21 on the bonding area (between the first bonding part 5 and the second bonding part 62) has a projection area that accounts for about 5% to about 10% of the bonding area, and a projection of the heat-dissipating elements 52 (local bridge case) on the bonding area has a surface area that accounts for about 2.5% to about 5% of the bonding area. Thus, the bonding capability of the first bonding part 5 is least affected.

As shown in FIG. 5, in some other embodiments, the heat-dissipating unit is formed in the entire first bonding layer 51. That is, the heat-dissipating elements 52 are distributed throughout the first bonding layer 51, and over the entire device portion 2. That is, the heat-dissipating elements 52 are formed in region(s) directly above the hot zone area(s) 21, and in regions that are outside of the hot zone area(s) 21. Such heat-dissipating elements 52 of such heat-dissipating unit are known as global bridges. As shown exemplarily in FIG. 5, the heat-dissipating elements 52 may be evenly distributed throughout the first bonding layer 51 (the heat-dissipating elements 52 are equally spaced apart from each other, but are not limited thereto). The global bridges are suitable for general application in semiconductor structures with different designs. For instance, very often, it is difficult to identify, or predict location(s) of the hot zone area(s) 21 in the device portion 2. In addition, in some cases, when the hot zone areas 21 have a relatively large size, or are present at a relatively high density, e.g., the projection area (of the hot zone areas 21 on the bonding area) accounts for more than approximately 10% of the bonding area, one may consider to utilize the global bridges. In some embodiments, a projection of the heat-dissipating elements 52 (global bridge case) on the bonding area has a surface area that accounts for about 10% to about 30% of the bonding area.

Despite possible application(s) of each of the global bridge and local bridge are discussed, one may still, determine using which one of the global bridge and local bridge based on practical needs, and are not limited to the scenario as described above.

In some embodiments, the heat-dissipating elements 52 are formed by depositing the heat-dissipating material (not shown) over the first bonding layer 51 and filling the trenches 520 (see FIG. 3); followed by removing an excess amount of the heat-dissipating material by a planarization process (e.g., chemical-mechanical polishing (CMP), but is not limited thereto), so that the heat-dissipating elements 52 of the heat-dissipating unit are formed in and exposed from the first bonding layer 51. The deposition of the heat-dissipating material may be performed by any suitable deposition process, such as CVD, ALD, but are not limited thereto. Other suitable processes, materials and/or thickness for the heat-dissipating unit are within the contemplated scope of the present disclosure.

Please note that the processes of forming the heat-dissipating elements 52 (including forming the trenches 520) in the first bonding layer 51 may be similar to the processes of forming metal, e.g., the conductive elements 32, 33, in the ILD 31 of the front interconnect portion 3 (see FIG. 13) in terms of processes and/or operation parameters settings employed. For instance, in some embodiments, the heat-dissipating elements 52 may have a pitch and/or a critical dimension similar to those of the conductive elements 32, 33, and thus the heat-dissipating elements 52 may be formed using current process flow of forming the conductive elements 32, 33 without having to develop new process flow.

After step 103, the first bonding part 5 including the first bonding layer 51 and the heat-dissipating unit formed in the first bonding layer 51 is obtained. In the subsequent steps, the heat-dissipating elements 52 are exemplarily configured as local bridges, but are not limited thereto.

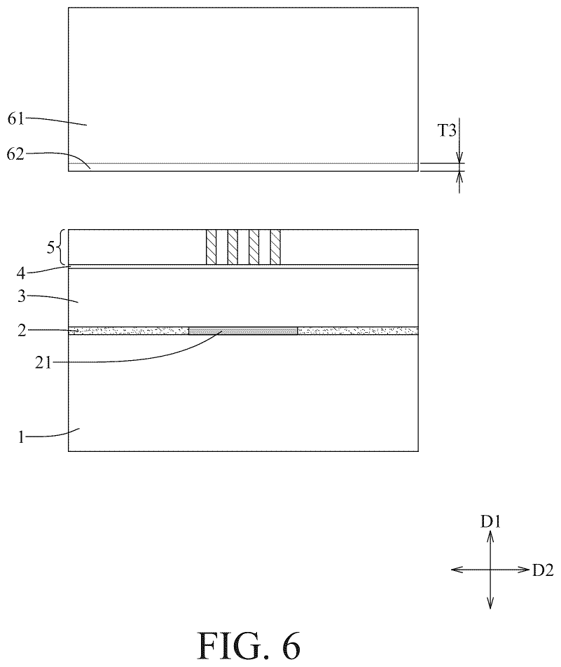

Referring to FIG. 1 and the examples illustrated in FIGS. 6 and 7, the method proceeds to step 104, where the carrier substrate 61 is bonded to the device portion 2 through the first bonding part 5 and the second bonding part 62.

In some embodiments, step 104 includes forming the second bonding part 62 on the carrier substrate 61 (see FIG. 6); followed by bonding the second bonding part 62 to the first bonding layer 51 (see FIG. 7). In forming the carrier substrate 61 and the second bonding part 62, a substrate layer (not shown, which commonly have an incoming size of approximately 765 μm, but is not limited thereto) that is independent from the structure shown in FIG. 4 or 5 is provided. The substrate layer may include a material similar to that of the base substrate 1 described with reference to FIG. 2, and details thereof are omitted for the sake of brevity. The substrate layer is subjected to an oxidation treatment, such that a surface region of the substrate layer is oxidized and is formed into the second bonding part 62, while a bottom region of the substrate layer remains unchanged and serves as the carrier substrate 61. In some embodiments, the substrate layer includes, or is made of silicon, and the second bonding part 62 includes, or is made of silicon oxide. In some embodiments, the oxidation treatment may be a heating treatment, but is not limited thereto. Other suitable materials and/or processes for forming the second bonding part 62 and the carrier substrate 61 are within the contemplated scope of the present disclosure. The second bonding part 62 may have a thickness T3 smaller than the thickness T2 of the first bonding layer 51 (see also FIG. 2). In certain embodiments, the thickness T3 of the second bonding part 62 ranges from about 0.01 μm to about 0.05 μm, such as from about 0.01 μm to about 0.035 μm, or from about 0.035 μm to about 0.05 μm, but are not limited thereto. Such thickness range permits sufficient bonding with the first bonding layer 51 without exhibiting additional and undesired thermal resistance between the device portion 2 and the carrier substrate 61 (see FIG. 9). In bonding of the second bonding part 62 to the first bonding part 5, one may freely determine to adopt any suitable bonding process and/or bonding parameters. In some embodiments, a fusion bonding method (e.g., oxide-oxide bonding) is adopted, but is not limited thereto. In some other embodiments, in addition to a bonding between the first bonding layer 51 and the second bonding part 62, the heat-dissipating unit is also bonded to the second bonding part 62). Other suitable materials and/or materials for the second bonding part 62 and the carrier substrate 61 are within the contemplated scope of the present disclosure.

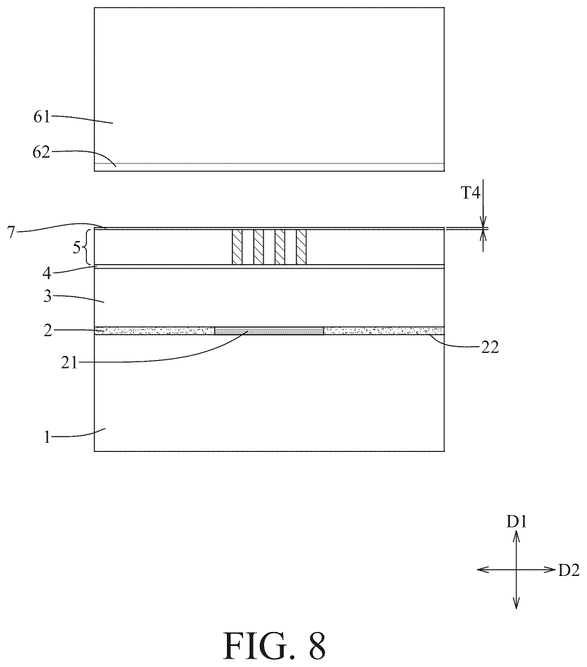

Referring to FIG. 8, in some embodiments, step 104 may further include, prior to performing the bonding process between the second bonding part 62 and the first bonding part 5, forming a third bonding part 7 over the first bonding part 5. As such, in the bonding process, the second bonding part 62 is bonded to the first bonding part 5 through the third bonding part 7.

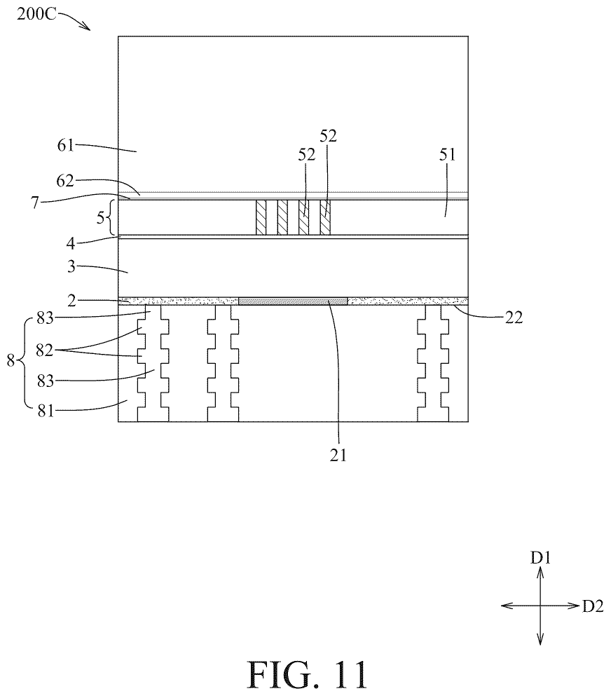

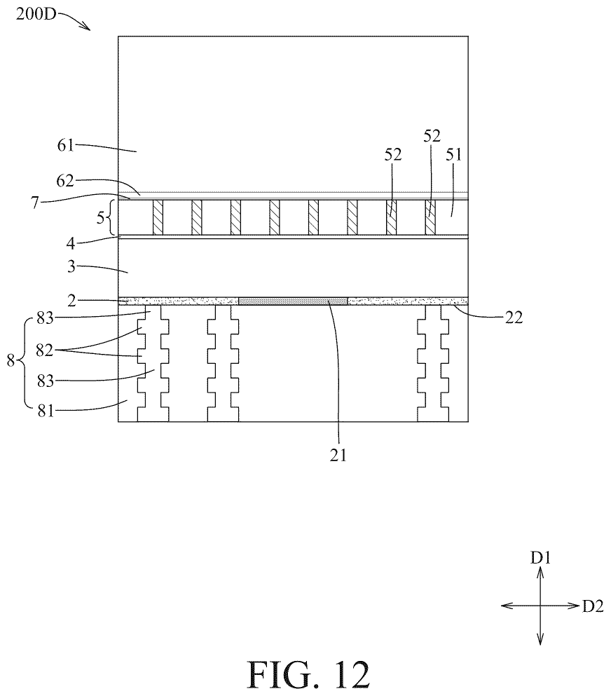

The third bonding part 7 is configured to further enhance bonding capability between the first and second bonding parts, 5, 62. The third bonding part 7 includes a material different from that of the first bonding layer 51, or that of the second bonding part 62. In some embodiments, the third bonding part 7 includes, or is made of a metal oxide, so as to ensure good thermal conductivity. The metal oxide may be titanium oxide, but is not limited thereto. The third bonding part 7 may be formed by a suitable deposition process, such as CVD, ALD, but are not limited thereto. The third bonding part 7 may have a thickness T4 smaller than the thickness T2 of the first bonding layer 51 (see also FIG. 2). In certain embodiments, the thickness T4 of the third bonding part 7 ranges from about 0.01 μm to about 0.03 μm, such as from about 0.01 μm to about 0.02 μm, or from 0.02 μm to about 0.03 μm. Such thickness range permits sufficient bonding with the second bonding part 2 without exhibiting additional and undesired thermal resistance between the device portion 2 and the carrier substrate 61 (see FIGS. 11 and 12). Other suitable materials, and/or process, and/or thickness for the third bonding part 7 are within the contemplated scope of the present disclosure. In some embodiment, the third bonding part 7 is bonded to the second bonding part 62 through any suitable bonding methods (e.g., a hybrid bonding method).

Referring to FIG. 1 and the example illustrated in FIG. 9, the method proceeds to step 105, where the base substrate 1 (see FIG. 8) is removed to expose a back surface 22 of the device portion 2, and a back interconnect portion 8 is formed on the back surface of the device portion 2. In some embodiments, from the back surface 22 of the device portion 2, the semiconductor fins and the isolation features (not shown) of the device portion 2 are exposed.

In some embodiments, step 105 includes flipping the structure shown in FIG. 7 upside down, such that the base substrate 1 faces upward; and then the base substrate 1 is to be removed using any suitable processes so as to expose the back surface 22 of the device portion 2. Step 105 then further includes forming the back interconnect portion 8 on the back surface of the device portion 2. Specifically, conductive features 82, 83 are formed in ILD feature 81, in which conductive features 82, 83 are electrically connected to the logic devices in the device portion 2. The conductive features 82 may each serve as a metal line or a metal layer, while the conductive features 83 may each serve as a contact via, but are not limited thereto. Possible materials for the ILD 81, the conductive features 82, 83 may be respectively similar to the materials for the ILD 31, the conductive features 32, 33 described with reference to FIG. 2, and details thereof are omitted for the sake of brevity. After forming the back interconnect portion 8, the structure may be flipped over again, so as to obtain the semiconductor structure 200A shown in FIG. 9.

The semiconductor structure 200A includes the device portion 2, the front and back interconnect portions 3, 8 that are respectively formed on the front side and the back side of the device portion 2, and the carrier substrate 61 that is bonded to the device portion 2 through the front interconnect portion 3, the protection layer 4, and the first and second bonding parts 5, 62. The heat-dissipating unit of the first bonding part 5 has a thermal resistance which is smaller than a thermal resistance of each of the first bonding layer 51 and the second bonding part 62. The heat-dissipating unit is spaced apart from the device portion 3 by merely the relatively thin protection layer 4, and is spaced apart from the carrier substrate 6 by the relatively thin second bonding part 62, so as to minimize any unnecessary additional thermal resistance, thereby achieving effective dissipation of heat energy away from the device portion 2 toward the carrier substrate 6.

In the heat-dissipating unit of the semiconductor structure 200A, the heat-dissipating elements 52 are arranged merely at the region in the first bonding layer 51 directly above the hot zone area 21 of the device portion 2, in which the hot zone area 21 is well-identified and has a relatively small size. In some embodiments, a projection of the heat-dissipating elements 52 on the device portion 2 is within the hot zone area 21. With such configuration, the heat-dissipating elements 52 occupy a relatively low surface percentage out of the bonding area, which is conducive in minimizing effect on the topography or bonding capability of the first bonding part 5 while achieving the purpose of effective heat dissipation.

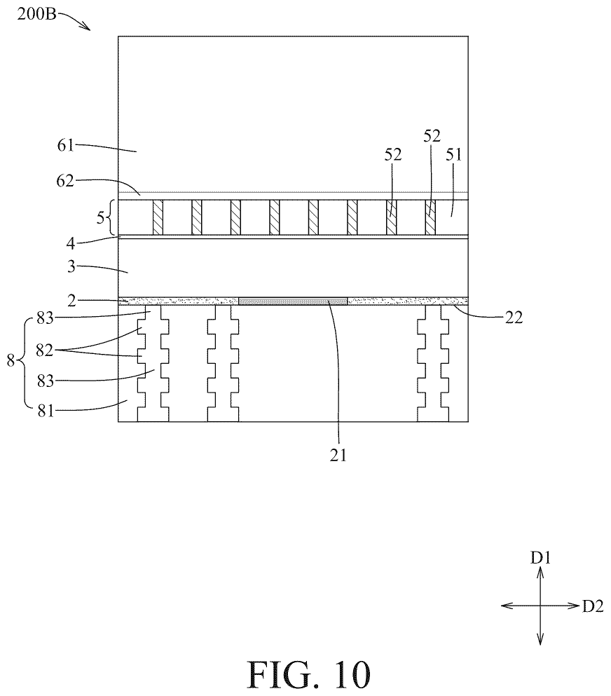

FIG. 10 illustrates a semiconductor structure 200B which is similar to the semiconductor structure 200A, except that the heat-dissipating elements 52 of the heat-dissipating unit have different arrangements from those of the semiconductor structure 200A shown in FIG. 9. It should be noted that the semiconductor structure 200B is a final structure obtained from the structure shown in FIG. 5. Specifically, in the semiconductor structure 200B, the heat-dissipating elements 52 are arranged over the entire device portion 2, instead of a predetermined region (e.g., over the hot zone area(s) 21). Such configuration permits a more generally applicable approach to scenarios such as unpredictable locations of the hot zone areas 21, or hot zone areas having a relatively large size, while maintaining the surface percentage of the heat-dissipating elements 52 at a low level to allow bonding between the first bonding part 5 and the second bonding part 62. In some embodiments, the global bridges (the heat dissipating elements 52) are formed throughout the entire first bonding layer 51 with an uneven distribution. For instance, in certain region(s) (e.g., at regions where the hot zone areas 21 are relatively densely packed), the heat dissipating elements 52 are arranged with a relatively higher density, while in some other region(s) (e.g., at peripheral regions where the hot zone areas 21 are not formed), the heat dissipating elements 52 are arranged with a relatively low density. Such heat dissipating elements 52 with uneven distribution may be achieved by adjusting parameters in forming the trenches 520 (see FIG. 3) as described in step 102, e.g., adjusting the patterns formed in a photomask used in the photolithography process, but is not limited thereto.

FIGS. 11 and 12 respectively illustrate semiconductor structures 200C, 200D, which are similar to the semiconductor structures 200A, 200B shown in FIGS. 9 and 10, respectively. The main difference is that, each of the semiconductor structures 200C, 200D further includes the third bonding part 7, such that the carrier substrate 61 is bonded to the device portion 2 therethough (and also through the first and second bonding parts 5, 62). It should be noted that the semiconductor structure 200C is obtained from the structure shown in FIG. 8. The third bonding part 7 is made of a metal oxide, which is known to have a thermal resistance smaller than that of each of the first bonding layer 51 and the second bonding part 6, so that the bonding capability between the first bonding part 5 and the second bonding part 6 is improved without sacrificing heat-dissipating capability of the semiconductor structures 200C, 200D.

FIG. 13 illustrates a semiconductor structure 200E which is similar to the semiconductor structure 200B shown in FIG. 10 in accordance with some other embodiments. In the semiconductor structure 200E, the device portion 2 exemplarily includes three parts (but are not limited thereto) that are separated from each other (it should be noted that the hot zone areas 21 are not shown in FIG. 13). Each of the front and back interconnect portions 3, 8 may independently include different number of metal layers, and are not limited to those shown in FIG. 13. In addition, the back interconnect portion 8 further includes metal layers 84 and contacts 85 that are connected to a corresponding one of the three parts of the device portion 2. Possible materials for the metal layers 84 and the contacts 85 may be similar to the materials for the conductive features 32, 33 described with reference to FIG. 2, and details thereof are omitted for the sake of brevity. The metal layers 84 and the contacts 85 cooperatively serve as a super power rail (SPR), so as to provide power to the device portion 2 from the back side (e.g., back surface) of the device portion 2. The back interconnect portion 8 may be connected to an external power contact 1001, and an I/O contact 1002. It is noted that, in some embodiments, the carrier substrate 61 may be thinned down to have a thickness ranging from about 200 μm to about 400 μm, but is not limited thereto. In some embodiments, the contacts 85 may respectively penetrate through the semiconductor fins (not shown) of the device portion 2 so as to be electrically connected to the logic devices in the device portion 2.

The embodiments of the present disclosure have the following advantageous features. By forming the heat-dissipating unit, which has a relatively low thermal resistance, in the first bonding layer 51, which has a relatively high thermal resistance, heat generated in the device portion 2 could be effectively dissipated away toward the carrier substrate 61 through the heat-dissipating unit. In the heat-dissipating unit, the heat-dissipating elements 52 may have different arrangement such that the heat-dissipating elements 52 can be adapted to different product design of the semiconductor structure. In addition, by controlling a surface percentage of the heat-dissipating elements 52, topography and bonding capability of the first bonding part 5 are least affected, so as to permit the first bonding part 5 to be readily bonded to the second bonding part 62, and thus to the carrier substrate 61. With enhanced heat dissipation capability, the semiconductor structures 200A, 200B, 200C, 200D, 200E may have improved performance and satisfactory operation speed.

In accordance with some embodiments of the present disclosure, a method for manufacturing a semiconductor structure includes: forming a device portion and a front interconnect portion on a base substrate; forming a first bonding part on the front interconnect portion opposite to the device portion, the first bonding part including a first bonding layer and heat-dissipating elements formed in the first bonding layer, a thermal resistance of the heat-dissipating elements being smaller than a thermal resistance of the first bonding layer; forming a second bonding part on a carrier substrate; and performing a bonding process to bond the second bonding part to the first bonding part.

In accordance with some embodiments of the present disclosure, forming the first bonding part includes: forming the first bonding layer on the front interconnect portion opposite to the device portion; forming trenches respectively at predetermined locations in the first bonding layer, each of the trenches extending from an upper surface of the first bonding layer to a lower surface of the first bonding layer; and forming the heat-dissipating elements respectively in the trenches.

In accordance with some embodiments of the present disclosure, the first bonding part and the second bonding part have a bonding area therebetween, and a projection of the heat-dissipating elements on the bonding area has a surface area that accounts for less than 30% of the bonding area.

In accordance with some embodiments of the present disclosure, the heat-dissipating elements are distributed throughout the first bonding layer.

In accordance with some embodiments of the present disclosure, the device portion has a hot zone area, and the heat-dissipating elements are formed at a region in the first bonding layer which is directly above the hot zone area.

In accordance with some embodiments of the present disclosure, the heat-dissipating elements include one of a metallic material, diamond, boron nitride, aluminum nitride, silicon carbide, and combinations thereof.

In accordance with some embodiments of the present disclosure, the method for manufacturing the semiconductor structure further includes forming a protection layer between the front interconnect portion and the first bonding part, such that a conductive feature in the front interconnect portion is insulated from the heat-dissipating elements of the first bonding part.

In accordance with some embodiments of the present disclosure, the method for manufacturing the semiconductor structure further includes: prior to performing the bonding process, forming a third bonding part over the first bonding part, a material of the third bonding part being different from a material of the first bonding layer; and in performing the bonding process, the second bonding part being bonded to the first bonding part through the third bonding part.

In accordance with some embodiments of the present disclosure, the third bonding part includes a metal oxide.

In accordance with some embodiments of the present disclosure, the third bonding part is formed with a thickness smaller than a thickness of the first bonding layer

In accordance with some embodiments of the present disclosure, the second bonding part is formed with a thickness smaller than a thickness of the first bonding layer

In accordance with some embodiments of the present disclosure, the first bonding layer has a thickness ranging from 0.1 μm to 1.2 μm.

In accordance with some embodiments of the present disclosure, a method for manufacturing a semiconductor structure includes: sequentially forming a device portion and a front interconnect portion on a base substrate in a vertical direction; forming a first bonding part on the front interconnect portion opposite to the device portion, the first bonding part including a first bonding layer and a heat-dissipating unit penetrating through the first bonding layer in the vertical direction, a thermal resistance of the heat-dissipating unit being smaller than a thermal resistance of the first bonding layer; forming a second bonding part on a carrier substrate; and performing a bonding process to bond the second bonding part to the first bonding part.

In accordance with some embodiments of the present disclosure, the heat-dissipating unit includes heating-dissipating elements that are spaced apart from each other in a horizontal direction transverse to the vertical direction.

In accordance with some embodiments of the present disclosure, the heat-dissipating elements are distributed over the device portion.

In accordance with some embodiments of the present disclosure, the heat-dissipating elements are distributed in position corresponding to a hot zone area of the device portion.

In accordance with some embodiments of the present disclosure, the first bonding part and the second bonding part have a bonding area therebetween, a projection of the hot zone area on the bonding area has a projection area that accounts for not greater than 10% of the bonding area.

In accordance with some embodiments of the present disclosure, the method for manufacturing the semiconductor structure further includes: removing the base substrate to expose a back surface of the device portion; and forming a back interconnect portion on the back surface of the device portion.

In accordance with some embodiments of the present disclosure, a semiconductor structure includes: a device portion, a front interconnect portion disposed on the device portion, a first bonding part, a substrate and a second bonding part. The first bonding part is disposed on the front interconnect portion opposite to the device portion. The first bonding part includes a first bonding layer and heat-dissipating elements formed in the first bonding layer. A thermal resistance of the heat-dissipating elements is smaller than a thermal resistance of the first bonding layer. The second bonding part is disposed between the carrier substrate and the first bonding part.

In accordance with some embodiments of the present disclosure, the first bonding part and the second bonding part have a bonding area therebetween, and a projection of the heat-dissipating elements on the bonding area has a surface area that accounts for less than 30% of the bonding area.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
forming a device portion and a front interconnect portion on a base substrate;
forming a first bonding part on the front interconnect portion opposite to the device portion, the first bonding part including a first bonding layer and heat-dissipating elements formed in the first bonding layer, a thermal resistance of the heat-dissipating elements being smaller than a thermal resistance of the first bonding layer;
forming a second bonding part on a carrier substrate; and
performing a bonding process to bond the second bonding part to the first bonding part.

2. The method of claim 1, wherein forming the first bonding part includes:
forming the first bonding layer on the front interconnect portion opposite to the device portion;
forming trenches respectively at predetermined locations in the first bonding layer, each of the trenches extending from an upper surface of the first bonding layer to a lower surface of the first bonding layer; and
forming the heat-dissipating elements respectively in the trenches.

3. The method of claim 2, wherein the first bonding part and the second bonding part have a bonding area therebetween, and a projection of the heat-dissipating elements on the bonding area has a surface area that accounts for less than 30% of the bonding area.

4. The method of claim 1, wherein the heat-dissipating elements are distributed throughout the first bonding layer.

5. The method of claim 1, wherein the device portion has a hot zone area, and the heat-dissipating elements are formed at a region in the first bonding layer which is directly above the hot zone area.

6. The method of claim 1, wherein the heat-dissipating elements includes one of a metallic material, diamond, boron nitride, aluminum nitride, silicon carbide, and combinations thereof.

7. The method of claim 1, further comprising forming a protection layer between the front interconnect portion and the first bonding part, such that a conductive feature in the front interconnect portion is insulated from the heat-dissipating elements of the first bonding part.

8. The method of claim 1, further comprising:
prior to performing the bonding process, forming a third bonding part over the first bonding part, a material of the third bonding part being different from a material of the first bonding layer;
in performing the bonding process, the second bonding part being bonded to the first bonding part through the third bonding part.

9. The method of claim 8, wherein the third bonding part includes a metal oxide.

10. The method of claim 8, wherein the third bonding part is formed with a thickness smaller than a thickness of the first bonding layer.

11. The method of claim 1, wherein the second bonding part is formed with a thickness smaller than a thickness of the first bonding layer.

12. The method of claim 1, wherein the first bonding layer has a thickness ranging from 0.1 μm to 1.2 μm.

13. A method for manufacturing a semiconductor structure, comprising:
sequentially forming a device portion and a front interconnect portion on a base substrate in a vertical direction;
forming a first bonding part on the front interconnect portion opposite to the device portion, the first bonding part including a first bonding layer and a heat-dissipating unit penetrating through the first bonding layer in the vertical direction, a thermal resistance of the heat-dissipating unit being smaller than a thermal resistance of the first bonding layer;
forming a second bonding part on a carrier substrate; and
performing a bonding process to bond the second bonding part to the first bonding part.

14. The method of claim 13, wherein the heat-dissipating unit includes heating-dissipating elements that are spaced apart from each other in a horizontal direction transverse to the vertical direction.

15. The method of claim 14, wherein the heat-dissipating elements are distributed over the device portion.

16. The method of claim 14, wherein the heat-dissipating elements are distributed in position corresponding to a hot zone area of the device portion.

17. The method of claim 16, wherein the first bonding part and the second bonding part have a bonding area therebetween, a projection of the hot zone area on the bonding area has a projection area that accounts for not greater than 10% of the bonding area.

18. The method of claim 13, after the bonding process, further comprising:
removing the base substrate to expose a back surface of the device portion; and
forming a back interconnect portion on the back surface of the device portion.

19. A semiconductor structure, comprising:
a device portion;
a front interconnect portion disposed on the device portion;
a first bonding part disposed on the front interconnect portion opposite to the device portion, the first bonding part including a first bonding layer and heat-dissipating elements formed in the first bonding layer, a thermal resistance of the heat-dissipating elements being smaller than a thermal resistance of the first bonding layer;
a substrate; and
a second bonding part disposed between the carrier substrate and the first bonding part.

20. The semiconductor structure of claim 19, wherein the first bonding part and the second bonding part have a bonding area therebetween, and a projection of the heat-dissipating elements on the bonding area has a surface area that accounts for less than 30% of the bonding area.
